(19) United States
(12) Patent Application Publication
(10) Pub. No.: US 2008/0210292 A1
(43) Pub. Date: Sep. 4, 2008

(54) Stationary Photovoltaic Module With Low Concentration Ratio of Solar Radiation

(76) Inventor: Natko Urli, Samobor (HR)

Correspondence Address: BROOKS KUSHMAN P.C., 1000 TOWN CENTER, TWENTY-SECOND FLOOR, SOUTHFIELD, MI, 48075, US

(21) Appl. No.: 11/914,257

(22) PCT Filed: May 16, 2006
(86) PCT No.: PCT/HR06/00011

§ 371 Date: Nov. 13, 2007

(30) Foreign Application Priority Data
May 16, 2005 (HR) P20050434A

(51) Int. Cl. H01L 31/052; H01L 31/0232

(52) U.S. Cl. 136/246; 136/251

(57) ABSTRACT

Stationary photovoltaic module with low concentration of solar radiation that consists of sequentially interchanged rows of truncated compound parabolic concentrating (CPC) mirrors 14 and active photovoltaic segments made of crystalline silicon or submodules of thin layer photovoltaic semiconductor materials 13. The active photovoltaic segments are interconnected electrically, and the maximal height of metal symmetrical or asymmetrical mirrors, protected by an optically transparent coating, is equal approximately to the width of a single photovoltaic segment All parts of the module are assembled in a metal or plastic box 11 without a transparent front cover. The module can also be designed as a photovoltaic-thermal co-generator, intended for integration in building facades, if some tubes for water cooling 51 or channels for air cooling 42 are included at the rear side of the module.

### TECHNICAL FIELD

This invention deals with encapsulation of solar cells from crystalline semiconductor material or thin-film photovoltaic submodules into modules or panels of much larger active areas such as implemented in civil engineering and architecture (for instance, as BIPV elements).

The modules should be protected from harmful atmospheric influence. Starting from standard dimensions of solar cells or thin-film photovoltaic modules as manufactured in production facilities, they are combined with optically reflective mirrors and their dimensions should be adjusted accordingly.

### BACKGROUND ART

Solar cells and solar photovoltaic (PV) modules are direct converters of solar energy into electricity. There is a large difference in construction and interconnection of monocrystalline or polycrystalline single silicon solar cells into larger modules in comparison with thin-film solar cells from amorphous silicon or from some semiconductor compounds. The former are mutually connected electrically in series with aluminum foils by ultrasonic or thermocompression bonding while the later are deposited on a large area electrically insulated substrate in several thin semiconducting and contact layers, and, then, divided in single cells already interconnected in series by laser scribing. Interconnected crystalline solar cells are laminated and encapsulated finally between two glass plates or between one front glass plate and a non-transparent plate from some plastic material. Modules from amorphous silicon (a-Si) are already deposited on the front glass, so that another glass plate may encapsulate the module protected sometimes with a plastic frame, too.

Solar PV modules are sensitive to daylight, that is, to the direct and the diffused solar radiation, and, therefore, can produce electricity even during a cloudy weather. Their widespread utilization encompasses autonomous electricity sources, power plants, or as building integrated elements (BIPV) in new buildings or retrofitting walls and roofs of the existing buildings. They may be connected as well to the electrical grid.

In regions with higher insulation with a predominant direct radiation, it is beneficial to utilize solar PV modules with concentrators of solar radiation in the form of Fresnel lenses or linear parabolic mirrors that can reach the concentration ratio greater than 100. Concentration of solar radiation is accompanying with an increase of module temperature and a decrease in their conversion efficiency. Therefore, it is advantageous to cool them by water or air. The main idea of implementation of concentrators is the partial replacement of more expensive photovoltaic materials by less costly electrically passive ones, and obtaining higher yield in the converted energy. In order to utilize better the direct component of solar radiation, modules are not stationary but follow the apparent daily movement of the Sun. However, the tracking systems increase the total cost of such arrangements, and they are not economical compared to stationary ones in areas with a larger component of diffused radiation.

There is a special class of solar radiation concentrators, the so-called CPC (compound parabolic concentrators) which are closed to the thermodynamical limit of the concentration ratio (CR) equal to

CR=1/sin θ_{c}

for a specified acceptance half-angle θ_{c} and for the two-dimensional case.

They are compounded from one left and one right branch of two parabolas whose axes make an angle θ_{c} with the optical axis and whose focuses are at the right and the left edges of the absorber (PV element), correspondingly. All sun-rays within the nominal acceptance angle 2 θ_{c}, after one or more reflection, will reach the absorber. It is favorable to maintain a low average number of reflections as each reflection introduces losses to the incoming radiation.

A serious disadvantage of all CPC's is their large reflector area making them too costly in most applications. Fortunately, as the top portion of a CPC reflector is nearly normal to the aperture, and contributing, therefore, little concentration, it is possible to truncate a CPC to about half of its full height without compromising significantly its concentration ratio but saving substantially reflector material.

Most of the published theoretical work on truncated CPC's deals with their utilization in solar thermal collectors with the tubular absorber for a supply of sanitary water, and not for one-sided flat absorber such as in photovoltaic devices. Crystalline bifacial silicon solar cells have been used as absorbers with more complicated compound reflectors consisting of the segments of parabola, circle, and ellipse, with glass as a dielectric in front of the absorber, reaching the concentration ratio up to 30. Economy of such a construction has been questionable because of large dimensions of passive parts.

Two Swedish constructions represent closer approaches to this invention. The first, with large trough-type CPC's with CR equal to 2.55 where the height of concentrators is 5 times larger than the width of silicon crystalline solar cells, and, as such, it is not acceptable for facade integration. Such systems may be placed only on flat roofs of buildings or in the field. The second is intended for integration into facades, with CIGS modules as absorbers, and CR equal to 3 which uses only one half (one branch) of the parabola as a concentrator. It protrudes almost half a meter outward from the vertical wall and consumes a lot of reflector material.

### DISCLOSURE OF THE INVENTION

The primary idea of this invention is an attempt to decrease the production cost of solar photovoltaic modules by replacing a portion of more costly active photovoltaic material by less costly passive, light reflecting material while maintaining approximately constant the solar energy average conversion efficiency per unit area of the module.

As building integrated photovoltaic systems (BIPV) have a good chance to predominate on the near-term PV market, it has been of interest to modify standard south-oriented facades and roofs of various buildings by electricity producing PV modules and systems making them integral parts of building construction elements. For such an application, only stationary PV modules have an obvious advantage. In order to be able to utilize both direct and diffused components of solar radiation only the truncated compound parabolic concentrators (CPC) have been taken into consideration.

The second goal has been more specific. It is mostly relevant to a-Si module manufacturers producing smaller size modules, restricted by the size of the PECVD deposition chambers, and, as such, less competitive on the market. Instead of trying to encapsulate several modules in a larger panel, this invention offers a different route: cutting them even into smaller segments (submodules), normal to separated single cells, combining them with CPC mirrors, and reintegrating them mechanically and electrically into large panels suitable for BIPV application. If the height of the truncated CPC linear mirrors is equal approximately to the width of the PV absorber stripes (segments), providing concentration ratio close to 2, and covering approximately a half of the module area, the power density of such a composed module should be similar to the flat one without CPC mirrors. The optimal ratio of the height of reflectors (being proportional to the quantity and the cost of reflector materials) and the width (the size) of solar PV cells bonded in a row, or the width of a submodule from a thin film material depends upon the cost of these materials as well upon meteorological parameters such as the ratio of direct-to-diffuse radiation in a certain geographical region.

The CPC's are of trough shape, i.e. they concentrate light in two dimensions, and both branches of parabolas may be symmetrical or asymmetrical (when the length of the left and the right branch is not equal).

Here, we do not utilize a front transparent cover to the CPC's in order to protect a sensitive surface of the mirror, as it has been usually done, because we choose to use highly reflective (up to 95%) A1 foil shaped in the form of CPC mirrors and already protected by a transparent coating.

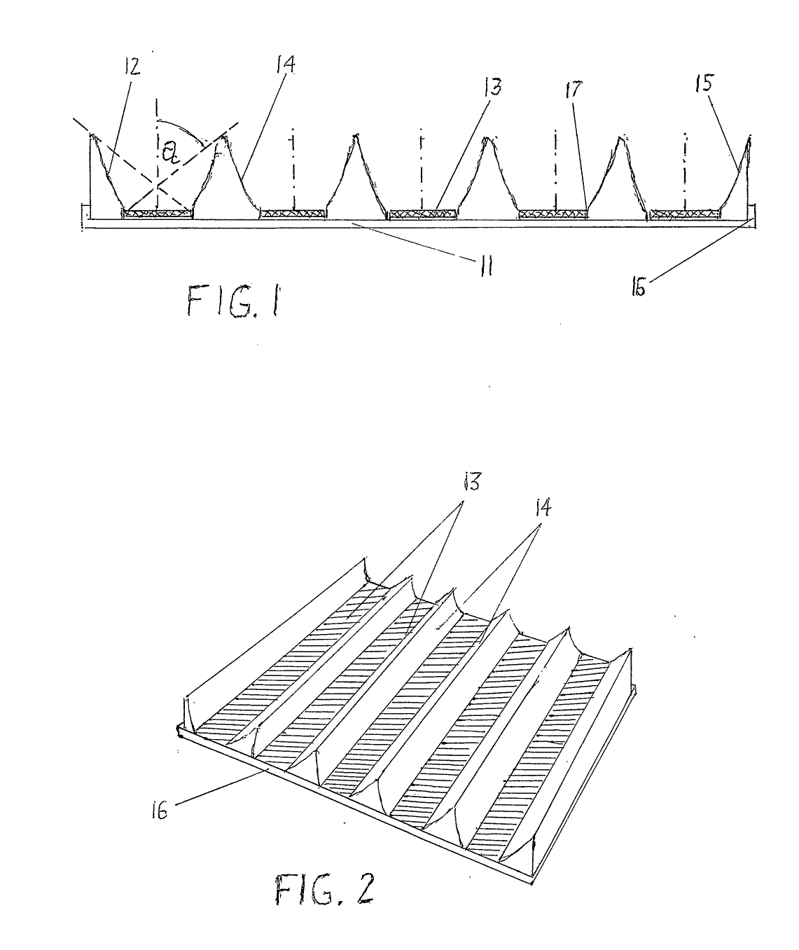

The module contains the rear A1 plate 11 onto which the rows of mirrors 14 and PV absorbers 13 are placed in pairs and fixed. The rear plate is inserted and attached to the rectangular frame. The both ends of the plate are bended upright 16, thus fixing the end branches of CPC mirrors (as shown in FIGS. 1 and 2).

The length of the composed module in the case of absorbers made from thin film PV submodules deposited on the glass superstrate (as in the case of a-Si) can be any multiple of the width of the PV-CPC pair determined mostly by the size of an original PV plate cut later into submodules. The submodules are electrically connected in series or in parallel inside the module. The hollow spaces beneath two mirror branches may be utilized for connectors or for placing a dc/ac inverter.

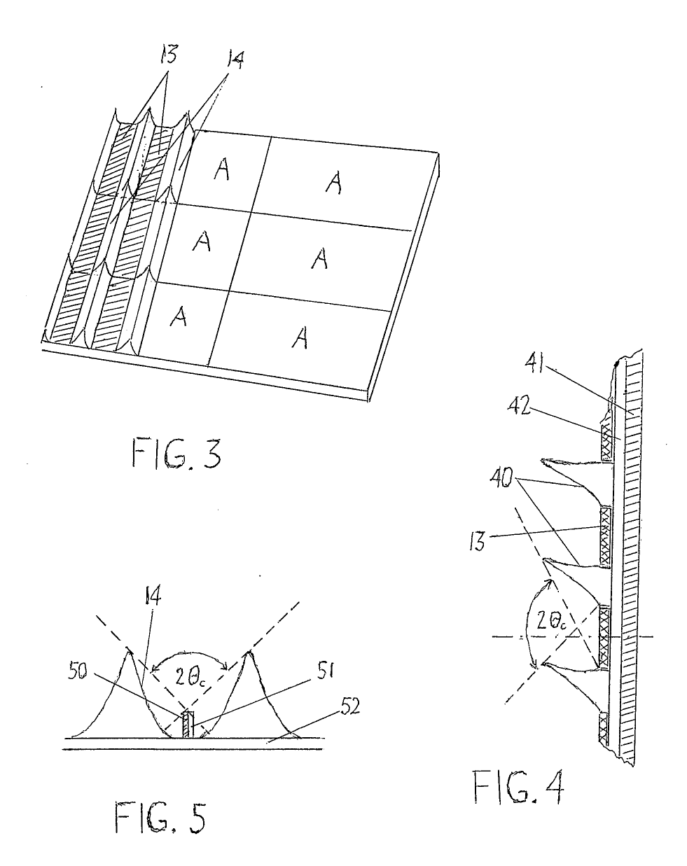

Several modules may be assembled in larger frames (FIG. 3) and as prefabricated elements combined with insulating layers utilized in construction of buildings.

An example of asymmetrical CPC module, as an element of south-oriented facade, is shown in FIG. 4. It enables a substantial increase in a converted energy compared to the performance of a vertically oriented flat plate PV module. The results may be even further improved if PV submodules are fixed at an angle from the vertical position. There is also a channel 42 for air-cooling of the module, thus providing cogeneration of electricity and heat.

Bifacial crystalline solar cells 50, absorbing the solar radiation from both sides, may be vertically mounted to the bottom of the CPC mirror (FIG. 5) and cooled by water flowing through the optically transparent plastic rectangular channel.

The symmetrical CPC modules mounted on the south-oriented roofs in the northern hemisphere should be inclined to the horizontal plane at an angle corresponding to the geographical latitude of the location, and oriented east-west in respect to their focal lines.

1. Stationary photovoltaic module with low concentration ratio of solar radiation that comprises mirrors in a trough shape of truncated compound parabolic linear concentrators (CPC) and photovoltaic active segments of crystalline silicon or submodules from thin photovoltaic semiconductor materials, the module comprising several rows of symmetrical or asymmetrical CPC metallic mirrors, overcoated by a transparent protection layer, and photovoltaic semiconductor materials mutually electrically interconnected, where the maximal height of mirror segments above the surface of active photovoltaic parts is equal approximately to the smaller dimension (width) of a single photovoltaic segment of the module.

2. Stationary photovoltaic module according to claim 1, wherein the photovoltaic segments and CPC mirrors are attached by gluing or by screws to the metal or plastic plate which constitutes the rear side of front open box or directly to its frame.

3. Stationary photovoltaic module according to claim 1, wherein the photovoltaic segments of the module with the asymmetrical mirrors are fixed inside the module at an angle from the horizontal plane corresponding to their maximal yearly electrical output when the module is integrated in or mounted on the vertical facade of a building.

4. Stationary photovoltaic module according to claim 1, wherein the lower branch of the parabola in the truncated linear CPC is replaced by a flat metallic mirror which is inclined at an angle from the horizontal plane in such a way to provide higher absorption of solar radiation by the photovoltaic segments due to smaller incident angles of solar rays and reduced reflection.

5. Stationary photovoltaic module according to claim 1, wherein submodules from thin film photovoltaic semiconductor material are produced by cutting larger size modules, fabricated by other known technologies, into smaller segments.

6. Stationary photovoltaic module according to claim 1, wherein tubes for water cooling or mutually connected channels for air cooling are built between the active photovoltaic segments and the rear plate of the box.
